(19) United States
(12) Patent Application Publication
(10) Pub. No.: US 2019/0362983 A1
(43) Pub. Date: Nov. 28, 2019

(54) SYSTEMS AND METHODS FOR ETCHING OXIDE NITRIDE STACKS

(71) Applicant: Applied Materials, Inc., Santa Clara, CA (US)

(72) Inventors: Daisuke SHIMIZU, Milpitas, CA (US); Wonseok LEE, Seoul (KR); Sean S. KANG, San Ramon, CA (US)

(21) Appl. No.: 16/398,314

(22) Filed: Apr. 30, 2019

Related U.S. Application Data
(60) Provisional application No. 62/675,666, filed on May 23, 2018.

(51) Int. Cl. H01L 21/311; H01J 37/32

(52) U.S. Cl. CPC H01L 21/31116; H01J 2237/3341; H01J 37/32082; H01J 37/3244

(57) ABSTRACT

Methods and apparatuses for etching oxide-nitride stacks to form features that include high aspect ratio features are discussed herein. The methods include providing an ionizable gas mixture to a processing chamber of an etch reactor. The ionizable gas mixture includes C₃H₂F₄ and a companion gas such a fluorocarbon. The ionizable gas mixture may be introduced to the chamber along with a carrier gas such as O₂ in addition to inert gases and other process gases. A plasma is formed from the ionizable gas mixture and etches the stack such that the etch selectivity of the stack is 1:1.

### PRIORITY CLAIM

This application claims priority to U.S. Provisional Patent Application 62/675,666, titled “Systems and Methods for Etching Oxide Nitride Stacks,” filed May 23, 2018, and incorporated by reference in its entirety herein.

### BACKGROUND

### Field

Embodiments of the present invention relate, in general, to etching of substrates and other materials. In particular, embodiments of the present invention relate to etching silicon oxide and silicon nitride and related materials.

### Description of the Related Art

Integrated circuits have evolved into complex devices that can include millions of transistors, capacitors and resistors on a single chip. The evolution of chip designs continually requires faster circuitry and greater circuit density. The demands for faster circuits with greater circuit densities impose corresponding demands on the materials used to fabricate such integrated circuits.

The production of silicon integrated circuits (IC) has placed difficult demands on fabrication steps to increase the number of devices while decreasing the minimum feature sizes on a chip. These demands have extended to fabrication steps including depositing layers of different materials onto difficult topologies and etching further features within those layers. Such a design that includes high aspect ratio features forms those features in a stack of alternating oxide layers and nitride layers to produce a desired structure. Etching a stack of alternating oxide layers and nitride layers (“ONON film stack”) effectively and efficiently with the appropriate critical dimensions and aspect ratios is a challenging task. Etching alternating oxide layers and nitride layers with high aspect ratios has presented difficult challenges, and is inefficient and costly using conventional gas mixtures, especially during batch processing.

Conventional processes to etch oxide-nitride (ONON) stacks involve numerous complex etching operations with various (7+) gases used in each step, these gases may or may not overlap among and between etching processes and the processing time for etching a batch can be over 1100 seconds. These multiple etching operations are employed to avoid undesirable results of etching during high-volume processes (HVP) e.g., batch processing of substrates. These undesirable results include mask (hole) entrance clogging, bowing and/or bending of the hole profile, striation, or other challenges that negatively impact the critical dimensions (CD) that are to be formed during etching. In an embodiment, the etching process is intended to produce a plurality of features such as holes and trenches through a layer or layers to expose a substrate. T

The plurality of features are of varying geometries and types and are each associated with a plurality of CD that include an average width throughout, feature top width, feature bottom width, sidewall profile, bottom profile, as well as other dimensions such as hole spacing. Trenches are narrow in one direction (depth measured perpendicular to the substrate) but wide in another direction (width measured parallel to the substrate). This is in contrast to holes which have a depth that exceeds a width by 20:1 or more for high aspect ratio features. Since trenches have a wide opening along one dimension, radicals that will etch nitrides and/or oxides will naturally propagate to the etch front. Accordingly, even for trenches having a high aspect ratio of above 20:1, the trenches are formed by both ions and radicals. The ions have directionality, while the radicals do not have directionality. In one embodiment, a majority of the etch species that etch trenches are ions, and a minority of the etch species are radicals. However, in some examples, the addition of the radicals changes the etch rate of the trenches as compared to the etch rate of holes.

The next generation in memory technology offers greater data storage in a smaller physical space (footprint). Creating next generation technology in memory applications enables greater data storage in a smaller physical structure, these smaller structures presents some fabrication issues. One of these challenges presented is etching alternating oxide layers and nitride layers (“ONON film stack”) in an efficient and cost effective process to produce high aspect ratio (HAR) features with a depth:width ratio of 20:1 or greater. In some embodiments, a target HAR is a depth:width from about 40:1 to about 100:1. Alternating oxide layers and nitride layers are included in the design of devices ultimately used in creating a device's memory gates. The current fabrication processes for etching multiple alternating oxide layers and nitride layers to produce high aspect ratio features typically use complex recipes, multiple process operations, and a multitude of conventional etch gases. This processing leads to high processing costs, decreases process efficiency, and further makes it difficult to create specialized high aspect ratio features with intricate geometries.

Thus, there remains a need for improved systems and methods for etching ONON film stacks.

### SUMMARY

The present disclosure generally relates to etching target materials including oxide-nitride layer stacks. In one example, a method of etching a substrate includes: providing an ionizable gas mixture to a processing chamber of an etch reactor, wherein the ionizable gas mixture includes C₃H₂F₄ and C₃F₆; forming a plasma from the ionizable gas mixture. In some examples, forming the plasma includes producing a plurality of ions from ionizable gas mixture. The method further includes etching a stack of alternating oxide and nitride layers formed on a substrate using the plurality of ions to form a plurality of features through the stack. Further in this example, an aspect ratio of each feature of the plurality of features is from 20:1 to 100:1.

In another example, a method of etching an oxide-nitride stack includes: disposing, in a processing chamber, a gas mixture comprising: C₃H₂F₄, a companion gas, and O₂. The C₃H₂F₄ includes a volume % of the gas mixture from 15 vol. % to 45 vol. %, the companion gas includes a volume % of the gas mixture from 15 vol. % to 50 vol. %, and the O₂ includes a volume % of the gas mixture from 10 vol. % to 40 vol. %. Subsequently, a substrate is positioned in the processing chamber, the substrate includes a plurality of alternating oxide and nitride layers. The example method further includes etching, in response to exposure to the gas mixture, a plurality of features in the plurality of alternating oxide and nitride layers.

In another example, a method includes: providing an ionizable gas mixture to a processing chamber of an etch reactor, wherein the ionizable gas mixture includes C₃H₂F₄ and a companion gas; forming a plasma from the ionizable gas mixture; and etching, via the plasma, a stack. The stack includes a plurality of alternating oxide and nitride layers to form a plurality of holes through the stack to selectively expose portions of the substrate.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a sectional view of a semiconductor processing chamber which is used to etch a material layer according to embodiments of the present disclosure.

FIG. 2 is a method of etching a film stack according to embodiments of the present disclosure.

FIGS. 3-6 are partial schematic cross-sections of film stacks according to embodiments of the present disclosure.

FIGS. 7 and 8 are partial schematic cross-sections of film stacks after convention etching.

FIG. 9 is a partial schematic illustration of a film stack etched according to certain embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The present disclosure is about etching oxide-nitride stacks (ONON), in particular SiₓN_{y} and SiₓO_{y} stacks. Reactive ion etching (RIE) of ONON stacks can be done with various gas combinations, including CH₂F₂ in combination with C₄F₆ and/or C₄F₈. However, this combination can present challenges with etch selectivity control. For example, etching methods are provided for etching high aspect ratio features into a film stack of alternating oxide layers and nitride layers. The etching of a film stack having alternating layers of oxides and nitrides is performed in a single etch operation. This is in contrast to conventional etching methods that use seven or more gases across a plurality of operations that takes more than 1100 seconds to complete. In an embodiment of the present disclosure, an ionizable gas mixture containing C₃H₂F₄ and a companion gas, is ionized using the application of RF power to a processing chamber to form a plasma suitable for etching high aspect ratio (an average of depth:width of 20:1-100:1 or more) features into a stack of alternating oxide layers and nitride layers. The companion gas is according to a formula CₓF_{y}. In one example, each of x and y in the formula CₓF_{y} are at least 1. Other gases, for example hydrogen-free fluorocarbons are added to the gas mixture to improve or control oxide etch rates and/or nitride etch rates. Additionally, in various embodiments, gases are introduced for polymer generation control or as a carrier gas. In an embodiment, a thickness of an ONON film stack etched according to methods of the present disclosure is from about 90 to about 130 pairs (180-260 oxide and nitride layers total), and having a total thickness of 4000 to 8500 nm.

Embodiments of the present invention provide methods to create a plurality of features in a stack of alternating oxide layers and nitride layers using C₃H₂F₄ and a companion gas. The companion gas is a fluorinated gas such as CₓF_{y}. Thus, in one example of an etchant gas mixture, the mixture includes C₃F₆. In another example, O₂ is used along with the C₃H₂F₄and the companion gas, so the etchant gas mixture includes C₃H₂F₄ and C₃F₆ and O₂ In an embodiment, the C₃H₂F₄ gas is ionized along with the companion gas in the presence of O₂, producing plasma with desirable pluralities of ions, radicals, and various molecules. The plasma can be formed by applying power to the processing chamber, the power applied can be from 400 kHz to 121 MHz and, in some examples, the power applied to the processing chamber is 2 MHz. These pluralities of ions and various molecules selectively etch the oxide and nitride layers on a substrate, creating consistently-sized, “clean” (e.g., meeting the critical dimensions (CD)) features some of which include high aspect ratio features. In an embodiment, when the oxide layers are etched at the same rate as the nitride layers, a plurality of desired features are formed with CDs such that a sidewall profile is perpendicular to a substrate on which the ONON film stack is disposed. As discussed herein, “etch selectivity” is a ratio of etch rates between two materials, and an “etch rate” of a material, which can differ depending upon the feature being formed by the etching, is the rate at which material is removed during etching and is measured as depth/time, such as Angstroms/second or nm/minute. Thus, in one example, if a first material has an etch rate of 10 nm/min and a second material has an etch rate of 20 nm/min, the etch selectivity would be 10:20 or 1:2 under those conditions. Due to the alternating oxide and nitride layers on the substrate, both ions that etch nitride layers and ions that etch oxide layers should be propelled to the etch front. By managing the ratio of the etch gas species that are provided, as discussed herein, the ratio of ions that will etch oxides (e.g., ions containing F) to the ratio of ions that will etch nitride (e.g., ions containing H) is controlled.

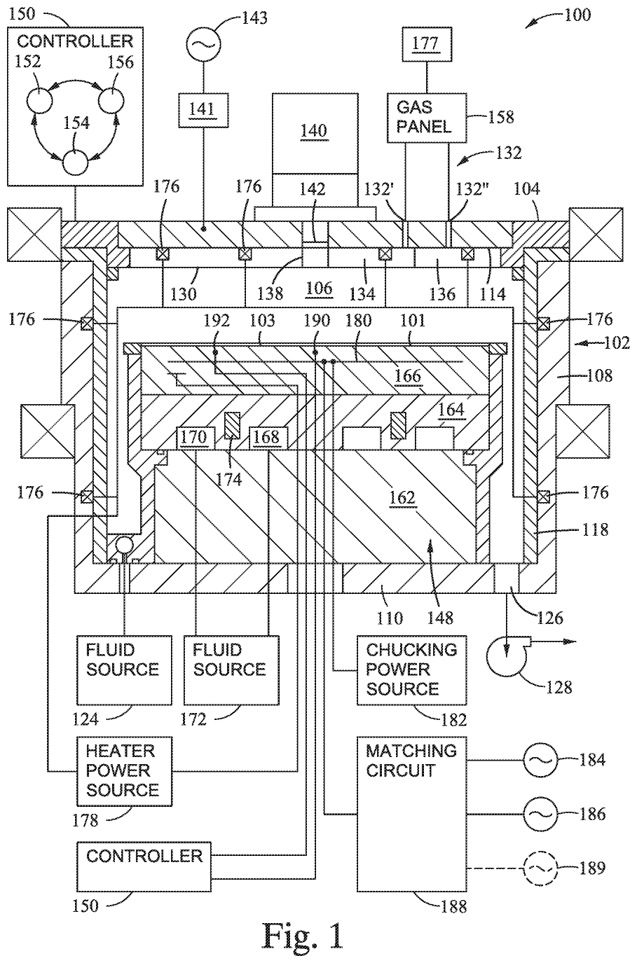

FIG. 1 is a sectional view of one embodiment of a processing chamber 100 suitable for performing an etching process to etch a material layer on a substrate using cycled and synchronized RF pulses according to embodiments of the present disclosure to etch a plurality of features in ONON film stacks. Although the processing chamber 100 is shown including a plurality of components that enable superior etching and trimming performance, it is contemplated that other processing chambers are adaptable to benefit from one or more of the inventive features disclosed herein.

In an embodiment, the processing chamber 100 includes a chamber body 102 and a lid 104 which enclose an interior volume 106. The chamber body 102 is typically fabricated from aluminum, stainless steel, quartz, or other suitable material. The chamber body 102 generally includes sidewalls 108 and a bottom 110. A substrate support pedestal access port (not shown) is generally defined in a sidewall 108 and selectively sealed by a slit valve to facilitate entry and egress of a substrate 101 from the processing chamber 100. In various embodiments discussed herein, a substrate 101 has an ONON film stack (not shown) formed thereon. An exhaust port 126 is defined in the chamber body 102 and couples the interior volume 106 to a pump system 128. The pump system 128 generally includes one or more pumps and a throttle valve utilized to evacuate and regulate the pressure of the interior volume 106 of the processing chamber 100. In one embodiment, the pump system 128 maintains the pressure inside the interior volume 106 at operating pressures typically between about 10 mT to about 500 mT.

In an embodiment, the lid 104 is sealingly supported on the sidewall 108 of the chamber body 102. The lid 104 may be opened to allow access to the interior volume 106 of the processing chamber 100 for maintenance. The lid 104 includes a window 142 that facilitates optical process monitoring. In one embodiment, the window 142 is comprised of quartz or other suitable material that is transmissive to a signal utilized by an optical monitoring system 140 mounted outside the processing chamber 100. The optical monitoring system 140 is positioned to view at least one of the interior volume 106 of the chamber body 102 and/or the substrate 101 positioned on a substrate support pedestal assembly 148 through the window 142. The optical monitoring system 140 is coupled to the lid 104 and facilitates an integrated deposition process that uses optical metrology to provide information that enables process adjustment to compensate for incoming substrate pattern feature inconsistencies (such as critical dimension (CD) variation and the like), provide process state monitoring (such as plasma monitoring, temperature monitoring, and the like) as needed.

A gas panel 158 is coupled to the processing chamber 100 to provide process and/or cleaning gases to the interior volume 106, including the mixture of etchant gases discussed herein, as well as carrier gases, inert gases, and other process gases employed in substrate of substrate batch processing. In the embodiment depicted in FIG. 1, inlet ports 132′, 132″ are provided in the lid 104 to allow gases to be delivered from the gas panel 158 to the interior volume 106 of the processing chamber 100. In one embodiment, the gas panel 158 is adapted to provide fluorinated process gas through the inlet ports 132′, 132″ and into the interior volume 106 of the processing chamber 100. In one embodiment, the process gas provided from the gas panel 158 includes various gas types including combinations of a fluorinated gas, chlorine, and a carbon containing gas, an oxygen gas, a nitrogen containing gas and a chlorine containing gas. Some or all of these types of gases are employed in various combinations discussed herein to etch ONON film stacks.

Further in an embodiment of FIG. 1, a showerhead assembly 130 is coupled to an interior surface 114 of the lid 104. The showerhead assembly 130 includes a plurality of apertures that allow the gases flowing through the showerhead assembly 130 from the inlet ports 132′, 132″ into the interior volume 106 of the processing chamber 100 in a predefined distribution across the surface of the substrate 101 being processed in the processing chamber 100.

A remote plasma source 177 is optionally coupled to the inlet ports 132′ and 132″ to facilitate providing a dissociated cleaning gas into the interior volume 106. A RF source power 143 is coupled through a matching network 141 to the showerhead assembly 130. The RF source power 143 typically is capable of producing up to about 4000 Watt tunable frequency in a range from about 50 kHz to about 200 MHz. During an etch process in the processing chamber, an RF source power from 2500 W to 4500 W and an RF bias power from 10000 W to 20000 W may be applied to the processing chamber 100 to form and maintain a plasma. The showerhead assembly 130 additionally includes a region 138 that is transmissive to an optical metrology signal. The optically transmissive region 138 is suitable for allowing the optical monitoring system 140 to view the interior volume 106 and/or the substrate 101 positioned on the substrate support pedestal assembly 148. In one embodiment, the optically transmissive region 138 includes a window 142 to prevent gas leakage through the optically transmissive region 138. The window 142 is a sapphire plate, quartz plate or other suitable material. In an embodiment, the window 142 is formed in the lid 104.

In one embodiment, the showerhead assembly 130 is configured with a plurality of zones. Each zone of the plurality of zones can be controlled separately to allow for separate control of gas flowing into the interior volume 106 of the processing chamber 100. In the embodiment FIG. 1, the showerhead assembly 130 has an inner zone 134 and an outer zone 136 that are separately coupled to the gas panel 158, respectively, through separate inlet ports 132′, 132″. The substrate support pedestal assembly 148 is positioned in the interior volume 106 of the processing chamber 100 below the gas distribution (showerhead) assembly 130.

The substrate support pedestal assembly 148 holds the substrate 101 during processing. The substrate support pedestal assembly 148 generally includes a plurality of lift pins (not shown) positioned therethrough. The plurality of lift pins are configured to lift the substrate 101 from the substrate support pedestal assembly 148 and facilitate exchange of the substrate 101 with a robot (not shown). The robot is used to transfer the substrate 101 into and out of the processing chamber 100. An inner liner 118 closely circumscribes the periphery of the substrate support pedestal assembly 148. A second fluid source 124 may be employed in cooling the liner 118. In one embodiment, the substrate support pedestal assembly 148 includes a mounting plate 162, a base 164 and an electrostatic chuck 166. The mounting plate 162 is coupled to the bottom 110 of the chamber body 102 includes passages for routing utilities, such as fluids, power lines and sensor leads, among others, to the base 164 and the electrostatic chuck 166. The electrostatic chuck 166 includes at least one clamping electrode 180 for retaining the substrate 101 below showerhead assembly 130. In an embodiment, the electrostatic chuck 166 is driven by a chucking power source 182 to develop an electrostatic force that holds the substrate 101 to the chuck surface, as is conventionally known. Alternatively, the substrate 101 is retained to the substrate support pedestal assembly 148 by clamping, vacuum, or gravity.

At least one of the base 164 or electrostatic chuck 166 includes at least one optional embedded heater 176, at least one optional embedded isolator 174 and a plurality of conduits 168, 170 to control the lateral temperature profile of the substrate support pedestal assembly 148. The conduits 168, 170 are fluidly coupled to a fluid source 172 that circulates a temperature regulating fluid therethrough. The heater 176 is regulated by a power source 178. The conduits 168, 170 and the heater 176 are utilized to control the temperature of the base 164. The temperature control enables the heating and/or cooling of the electrostatic chuck 166 and ultimately, the temperature profile of the substrate 101 positioned thereon. The temperature of the electrostatic chuck 166 and the base 164 is monitored using a plurality of temperature sensors 190, 192. In an embodiment, the electrostatic chuck 166 further includes a plurality of gas passages (not shown), such as grooves, that are formed in a substrate support pedestal supporting surface of the chuck 166 and fluidly coupled to a source of a heat transfer (or backside) gas, such as He. In operation, the backside gas is provided at controlled pressure into the gas passages to enhance the heat transfer between the electrostatic chuck 166 and the substrate 101. In alternate embodiments, the plurality of heaters 176 are positioned not only in the base 164 or electrostatic chuck 166 but are also positioned in the showerhead assembly 130 and the chamber body 102. The substrate 101 may be held at a predetermined temperature during etching from 0° C.-80° C. via the heaters 176 in the base 164 or electrostatic chuck 166.

In one embodiment, the substrate support pedestal assembly 148 is configured as a cathode and includes an electrode 180 that is coupled to a plurality of RF power bias sources 184, 186. The RF bias power sources 184, 186 are coupled between two electrodes, the electrode 180 that is disposed in the substrate support pedestal assembly 148 and another electrode, such as the showerhead assembly 130 or ceiling (lid 104) of the chamber body 102. The RF bias power excites and sustains a plasma discharge formed from the gases introduced to the processing region of the chamber body 102.

In the embodiment depicted in FIG. 1, the dual RF bias power sources 184, 186 are coupled to the electrode 180 positioned in the substrate support pedestal assembly 148 through a matching circuit 188. The signal generated by the RF bias power 184, 186 is delivered through matching circuit 188 to the substrate support pedestal assembly 148 through a single feed to ionize the gas mixture provided in the processing chamber 100, thereby providing ion energy necessary for etching or other plasma enhanced process. The RF bias power sources 184, 186 are generally capable of producing an RF signal having a frequency from about 50 kHz to about 200 MHz and a power between about 0 Watts (W) and about 20000 W. An additional bias power source 189 is coupled to the electrode 180 to control the characteristics of the plasma.

In one example mode of operation, the substrate 101 is positioned on the substrate support pedestal assembly 148 in the processing chamber 100. A process gas mixture is introduced into the chamber body 102 through the showerhead assembly 130 from the gas panel 158. The vacuum pump system 128 maintains the pressure inside the chamber body 102 while removing by-products of etching. A controller 150 is coupled to the processing chamber 100 to control operation of the processing chamber 100. The controller 150 is configured to control the processing chamber 100 operations including loading and executing gas recipes to be used in pre-processing, feature formation (etching), and post-processing. The controller 150 includes a central processing unit (CPU) 152, a memory 154, and a support circuit 156 utilized to control the process sequence and regulate the gas flows from the gas panel 158. The CPU 152 is configured for use to include a processor sufficient for use in an industrial setting. The software routines can be stored in the memory 154, such as random access memory (RAM), read only memory, floppy, or hard disk drive, or other form of digital storage. The support circuit 156 is conventionally coupled to the CPU 152 and includes cache, clock circuits, input/output systems, power supplies, and the like. Bi-directional communications between the controller 150 and the various components of the processing chamber 100 are handled through numerous signal cables such that the etching programs and other processing programs in the methods discussed herein are executed. The etching and other processing programs discussed herein can be stored on the memory 154 which can also be described as a non-transitory computer-readable medium.

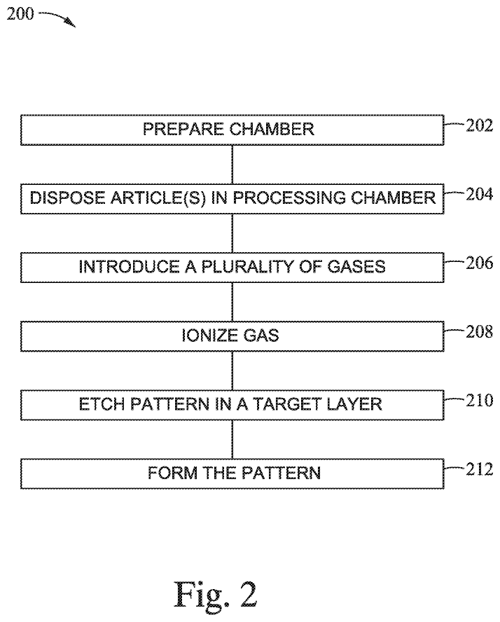

FIG. 2 is a flow diagram of method 200 of etching an ONON film stack according to embodiments of the present disclosure. The method 200 begins at operation 202, the processing chamber is prepared for processing a film stack or a plurality of film stacks having an ONON film stack. At operation 202, a portion of an etching program is executed by a controller such as the controller 150 from FIG. 1. As discussed above, the film stacks positioned in the processing chamber at operation 202 include substrates with an ONON film stack and, in some embodiments, a hard mask layer or other layers depending upon the embodiment. In an embodiment at operation 202, the temperature of the substrate is regulated from 0° C.-80° C. and held within that range during subsequent processing operations discussed below. In another example, the substrate temperature is maintained from 45° C.-55° C. with a target of 50° C. In an embodiment, during the processing chamber preparation operation 202, the processing chamber 100 is maintained at about 5 mT to about 50 mT and held within that range during ONON film stack processing. At operation 204, a film stack or a plurality of film stacks is positioned in a processing chamber configured to etch at least one target layer of the substrate. The substrate includes a plurality of stacked, alternating SiₓN_{y}/SiₓO_{y} layers.

At operation 206, a plurality of gases including ionizable gases and one of O₂ are introduced into the processing chamber. One or more inert gases may also be employed at operation 206. In one example, a H-containing gas and a F-containing gas are introduced at operation 206 in order to etch both the oxide and nitride layers of the ONON film stack. Embodiments of the method 200 simplify and improve control of CDs as compared to conventional etch processes by introducing new gas mixtures and/or etch chemistries that use C₃H₂F₄ a companion gas CₓF_{y}, in one example C₃F₆, and a carrier gas O₂. The inert gases discussed herein may be employed in processing in various quantities depending upon the embodiment. The gases discussed herein may be employed at a flow rate of 200 sccm to 1000 sccm. In one example, which can be combined with examples herein, the C₃H₂F₄ may be introduced at a flow rate of 100 sccm. In another example, which can be combined with other examples herein, the C₃F₆ is introduced at a rate of 150 sccm. In still another example, which can be combined with other examples herein the carrier gas is introduced at a rate of 100 sccm. One or more inert gases such as Ar, Kr or others may be introduced at a rate of 200 sccm depending upon the embodiment.

In an embodiment, the gases introduced at operation 206 are introduced via a gas panel such as the gas panel 158 in FIG. 1. The gases introduced at operation 206 may include C₃H₂F₄ and a companion gas according to the formula CₓF_{y}. In addition, a carrier gas such as O₂ is introduced at operation 206 via the gas panel 158. Each gas may be introduced separately or concurrently with the other gases, and, as discussed above, each gas may be introduced at a flow rate from 200 sccm to 1000 sccm.

At operation 208, the gases introduced at operation 206 are ionized in order to etch a pattern (a plurality of features) in at least one target layer of the film stack at operation 210. The ionization of the gases at operation 208 is enabled by using the RF source and bias power, such as 3500 W source power and 20000 W bias power. The substrate temperature during operation 208 may be from about 50˜100° C. This target layer is the ONON film stack which may have a thickness within a range from about 4000 nm thick to about 8500 nm thick or greater. In some examples, an etch rate (as exhibited during operation 210) of oxide layers in a target layer is within 10% of an etch rate of nitride layers in the target layer. In other examples, the relative etch rates may be within 5%, 2%, 1%, or less than 1%. The ionization at operation 206 may be performed in the processing chamber 100 discussed in FIG. 1. The ionization at operation 206 can include the RF power bias sources 184, 186, and/or 189, as well as RF source power 143. The pattern is formed at operation 212 in response to the ionized gas contacting an exposed area or areas in a masking layer. The pattern formed at operation 212 may include a plurality of holes and trenches that are formed to a predetermined set of critical dimensions (CD). In an embodiment, the etch selectivity of the oxide layers to the nitride layers is 1:1.

As discussed herein, a volume percentage of two or more components in a solution or a mixture is a measurement of a concentration of each of the two or more components in the solution or mixture. Accordingly, a volume percentage ratio is a ratio of the respective concentrations of each of the two or more components in the overall mixture. The gases ionized at operation 208 may be present in the etching chamber at a volume percentage ratio of the (C₃H₂F₄+the companion gas) to carrier gas from 80:20 to 30:70. The volume percentage ratio of the carrier gas to the C₃H₂F₄ in the etching chamber is from 0:100 to 90:10. In other examples, the volume percentage ratio of the carrier gas to the C₃H₂F₄ in the etching chamber is from 15:85 to 25:75. In one example at operation 206, the gases introduced are C₃H₂F₄, a companion gas, and O₂. The C₃H₂F₄ includes a volume percentage of the etchant gas mixture from 15 vol. % to 45 vol. %, the companion gas includes a volume % of the etchant gas mixture from 15 vol. % to 50 vol. %, and the O₂ includes a volume % of the etchant gas mixture from 10 vol. % to 40 vol. %. Thus, a ratio of the ionizable gas mixture: O₂ is from 90:10 to 60:40.

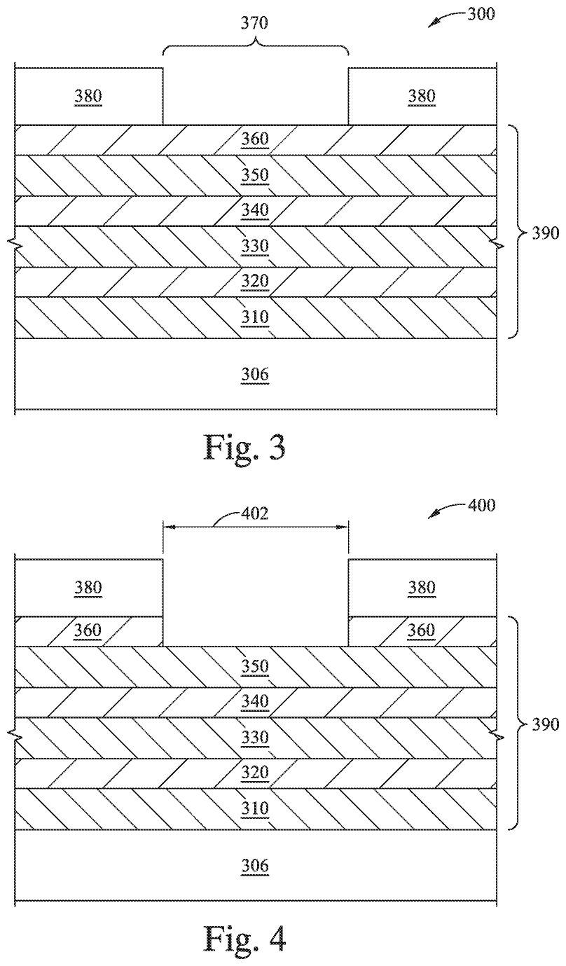

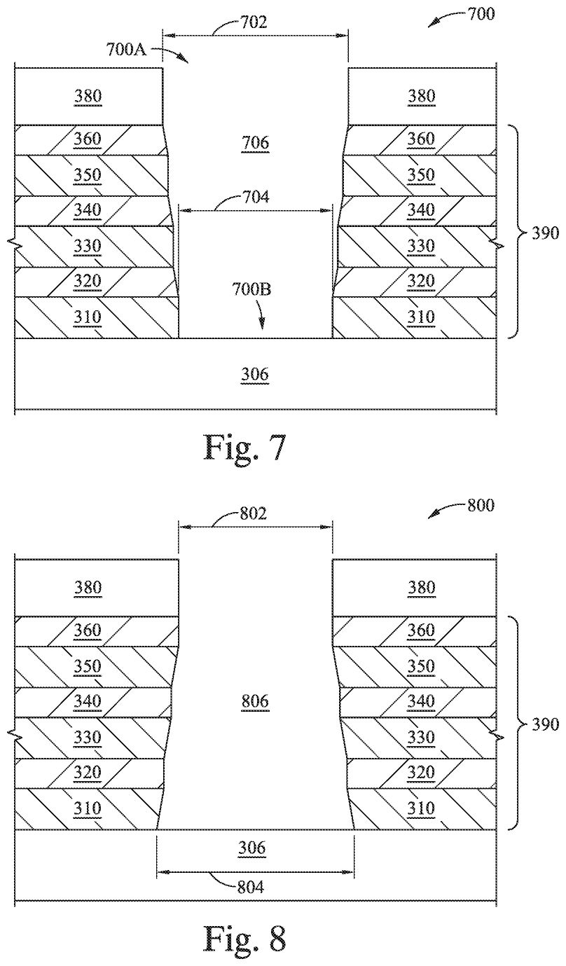

FIGS. 3-6 are schematic cross-sections of film stacks resulting from etching operations according to embodiments of the present disclosure. FIGS. 7 and 8 are partial schematic cross-sections of film stacks resulting from conventional etching operations. FIG. 3 is a cross-sectional view of a film stack 300 including a substrate 306 having a stack 390 of alternating oxide layers and nitride layers. The substrate 306 includes an ONON film stack 390 of oxide layers 360, 340, 320 and nitride layers 350, 330, 310. In one embodiment, the oxide layers 360, 340, 320 are SiO₂ layers and the nitride layers 350, 330, 310 are Si₃N₄ layers. Other oxide layers having the formula SiₓO_{y} are used in alternate embodiments. Additionally, other types of nitride layers having the formula of SiₓN_{y} are used in addition to or instead of Si₃N₄ layers. In one example, the nitride layers are 0% to 200% thicker than the oxide layers. In another example, the nitride layers 350, 330, 310 are approximately 20% thicker than the oxide layers 360, 340, and 320. In one embodiment, all of the oxide layers 360, 340, 320 have approximately the same thickness, and all of the nitride layers 350, 330, 310 have approximately the same thickness. In another example, an average thickness of the oxide layers is different than that of the nitride layers.

Further in FIG. 3, a pattern mask 380, which can be a hardmask, covers a top layer such as the oxide layer 360 in the stack 390. The pattern mask 380 can be a photoresist mask or a hard mask. Some pattern masks 380 used include a polysilicon hard mask, a metal hard mask, or a carbon hard mask. The metal hard mask can be a tungsten hard mask or a titanium nitride hard mask. The carbon hard mask can be fabricated from an amorphous carbon or a spin-on-carbon. The pattern mask 380 includes open areas 370 which expose the underlying layers to etchants during etching processes. The pattern mask 380 additionally includes covered regions that protect underlying layers from etchants. Regions of the stack 390 under the open areas 370 (towards the substrate 306) that are not protected by the pattern mask 380 undergo an etching process where portions of those regions are removed.

In an embodiment, the film stack 300 can be etched through the pattern mask 380 to create features having approximately the shape (width and/or geometry) of the openings in the pattern mask 380, as discussed in detail in FIGS. 4-6. In alternate embodiments, the etchants discussed herein are applied to etch features subsequently to the pattern mask 380 having openings formed. Various etchants are selected for etching the pattern mask 380 and/or the stack 390. These selections are generally based upon the pattern mask 380 material, thickness, and/or other factors in order to etch the pattern mask 380 at an etch rate to form the openings 370. Similarly, an etchant gas mixture is selected to etch the stack 390 depending upon the stack 390 composition, thickness, features to be patterned, or other aspects of the film stack 300. In an embodiment, during etching of the stack 390, an etchant gas mixture is selected and controlled (flow rate, composition, etc.) so that an etch selectivity of the nitride and oxide layers (stack 390) as compared to the pattern mask is approximately 5:1. In another embodiment, an etch selectivity of the nitride and oxide layers to the pattern mask is approximately 7:1. Thus, in some examples, the etch rate of the pattern mask 380 is at or below about 20% of the etch rate of the stack 390.

As discussed above, the etchants used may be employed in various volume ratios. In one example, volume percentage ratio of the carrier gas to the C₃H₂F₄ in the etching chamber is from 0:100 to 90:10 or, in other examples, is from 15:85 to 25:75. In some examples, the volume percentage ratio of the carrier gas to the C₃H₂F₄ in the etching chamber is from 10:90 to 40:60, or, in other examples, is from 15:85 to 25:75. The etchant mixture may be further defined by ranges of volume percentages of each gaseous component. In one example at operation 206, the gases introduced are C₃H₂F₄, a companion gas, and O₂. The C₃H₂F₄ includes a volume percentage of the etchant from 15 vol. % to 45 vol. %, the companion gas includes a volume % of the etchant from 15 vol. % to 50 vol. %, and the O₂ includes a volume % of the etchant from 10 vol. % to 40 vol. %.

FIG. 4 is a partial cross-sectional view of a film stack 400 including the substrate 306 and the stack 390 of oxide layers 360, 340, 320 and nitride layers 350, 330, 310 after the top oxide layer 360 has been etched. A plasma etch process similar to what is discussed herein has etched a feature 402 in the oxide layer 360 at the open area 370 in between adjacent mask portions of the pattern mask 380. Ionized molecules of a gas such as C₃H₂F₄ and at least one additional fluorocarbon are controlled in the processing chamber where the film stack 400 is positioned. The additional fluorocarbon can be C₃F₆. The ionized molecules of the C₃H₂F₄ and at least one additional fluorocarbon-containing gas perform an anisotropic etch of the oxide layer 360 at a predetermined oxide etch rate. In some embodiments, carrier gases, such as argon or oxygen, are included to counteract possible polymer generation. In one example, an etchant gas mixture of C₃H₂F₄ and a companion gas according to a formula CₓF_{y} are used together in the presence of O₂.

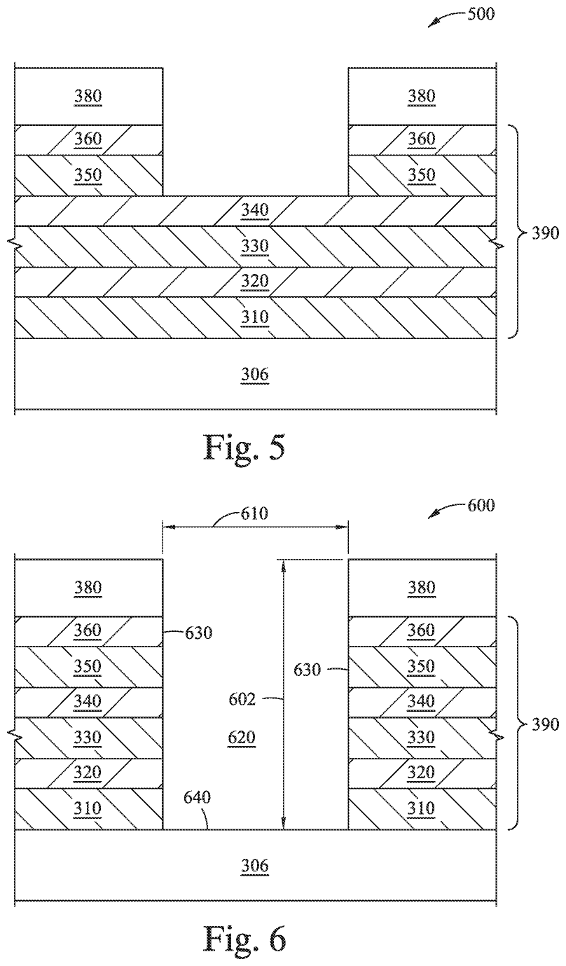

FIG. 5 depicts a cross-sectional view of a film stack 500 including the substrate 306 having the stack 390 of the oxide layers 360, 340, 320 and the nitride layers 350, 330, 310. FIG. 5 shows the film stack 500 after both of the nitride layer 350 has been etched and oxide layer 360 has been etched. Ionized molecules of a gas mixture of C₃H₂F₄ and at least one additional fluorocarbon are controlled in a processing chamber to perform an anisotropic etch of the oxide layer 360 at an oxide etch rate and then perform an anisotropic etch of the nitride layer 350 at a nitride etch rate.

FIG. 6 illustrates a sectional view of a film stack 600 including the substrate 306 having the stack 390 of oxide layers 360, 340, 320 and nitride layers 350, 330, 310 that has undergone an etch process. The process has etched a feature 620 in the oxide layers and in the nitride layers. The feature 620 has an aspect ratio of depth 602 to width 610. The aspect ratio can be measured for each feature 620 formed in a patterned substrate, such that an aspect ratio of a plurality of features including the feature 620 across a substrate is an average of the depth:width. In one example, the depth 602 to width 100 aspect ratio is between 20 to 1 (20:1) and 100 to 1 (100:1) in various embodiments. However, other aspect ratios are also possible. The etched feature 620 is a trench type feature or a pin hole type feature. The feature 620 has a depth 602 of up to 4 microns in some embodiments. In other embodiments, the feature 620 has a depth 602 of over 4 microns. In one embodiment, the feature 620 has a depth 602 of 3-4 microns. In another embodiment, the feature 620 has a depth from 4 microns to 7.5 microns or greater. The depth 602 in FIG. 6 has a constant width 610, such that the sidewalls 630 are perpendicular to the substrate 306 and parallel to each other in this cross-sectional view. A bottom 640 of the etched feature 620 is perpendicular to the sidewalls 630 and exposes the substrate 306.

In one embodiment, an oxide to nitride etch selectivity is approximately 1:1, meaning that the etch rate of the oxide layers is approximately equal to the etch rate of the nitride layers. Alternatively, the oxide to nitride etch selectivity is adjusted to cause a greater oxide etch rate or a greater nitride etch rate. The oxide to nitride etch selectivity is adjusted based on conditions of the oxide layers and/or nitride layers to be etched. For example, if a stack of alternating oxide layers and nitride layers has thicker nitride layers than oxide layers, then the nitride etch rate is increased in relation to the oxide etch rate. Similarly, if the oxide layer thickness is greater than the nitride layer thickness, then the oxide etch rate is increased relative to the nitride etch rate. In some embodiments the oxide-to-nitride etch selectivity is adjusted between approximately 1:2 and 2:1.

The etch rate for a feature (holes or trenches) may depend on factors such as the type of feature to be etched and a thickness of the stack. In particular, etched features are divided into the categories of trenches and holes. Holes have a horizontal diameter that is much less than a vertical depth of the holes. This creates a very high aspect ratio that is on the order of 20:1 to 100:1 or greater in some embodiments. To etch a hole in oxide and nitride layers on a substrate, a molecule first travels to the etch front at the bottom of the hole. Since radicals are neutral and thus have no charge, radicals are not propelled to the etch front by the electromagnetic field. The primary molecules that travel to the etch front are ions that are accelerated by the electromagnetic field produced by the etch reactor. The provided etch gases are decomposed into additional species, some of which are ions having charge. These ions are accelerated by the field and propelled to the etch front.

FIG. 7 shows a sectional view of a film stack 700 including the substrate 306 having the stack 390 of alternating oxide layers 360, 340, 320 and nitride layers 350, 330, 310 that has undergone an etch process. The process has etched a feature 706 in the oxide layers and in the nitride layers. In one embodiment, the feature 706 has a tapered cross sectional shape in which a bottom 700B of the feature is narrower than a top 700A of the feature. In one embodiment, an etch process having a higher oxide etch rate than a nitride etch rate produces features with a tapered cross section as shown, where a top diameter 702 is larger than a bottom diameter 704 such that the overall diameter decreases from the top diameter 702 to the bottom diameter 704. The example in FIG. 7 is an undesirable result of an etching environment that produces an inconsistent (stepped/angled) sidewall profile where the etch selectivity is not 1:1.

FIG. 8 illustrates a sectional view of a film stack 800 including the substrate 306 having the stack of alternating oxide layers 360, 340, 320 and nitride layers 350, 330, 310 that has undergone an etching operation. The etching operation has etched a feature 806 in the oxide layers and in the nitride layers. The feature 806 has a bowed cross section, where a top diameter 802 is smaller than a bottom diameter 804 such that the overall diameter increases from the top 802 to the bottom 804, this etched feature example is produced by a process having a higher nitride etch rate than oxide etch rate. The example in FIG. 8 is an undesirable result of an etching environment that produces an inconsistent (bowed) sidewall profile. The bowed sidewall profile shown in FIG. 8 can occur where there is not a controlled etch selectivity, e.g., the 1:1 etch selectivity as illustrated in FIGS. 3-6 and FIG. 9 discussed below.

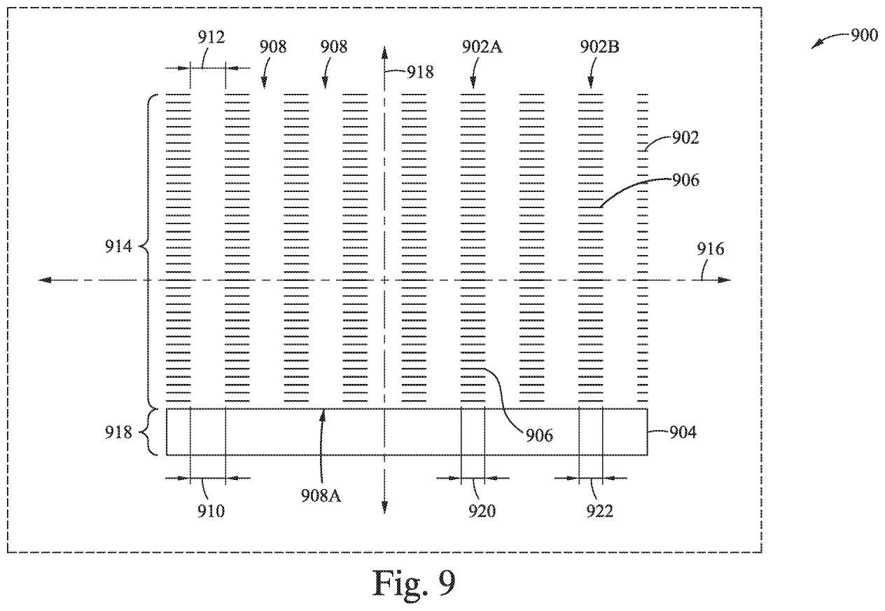

FIG. 9 is a partial schematic illustration of a film stack 900 etched according to certain embodiments of the present disclosure. FIG. 9 illustrates a plurality of etched features that may be similar to the feature discussed in FIG. 6 as having the depth 602. As shown in FIG. 9, a target layer 902 is formed on a substrate 904. In one example, the target layer 902 includes a plurality of alternating oxide-nitride stacks such as SiₓO_{y} and SiₓN_{y} layers as shown in FIGS. 3-6 above. The stack 914 may include 90-130 oxide-nitride pairs and be from about 4000 nm to about 8500 nm thick. FIG. 9 shows a coordinate system with a first axis 918 perpendicular to the substrate 904 and a second axis 916 parallel to the substrate 904 and perpendicular to the first axis 918.

Each etched feature 908 has a depth along the same direction as the first axis 918, a bottom width 910 and a top width 912. As shown herein, the depth of each etched feature 908 is such that a portion of the substrate 904 is exposed when the etched feature 908 is formed. In an embodiment, the CDs discussed herein include a sidewall 906 profile, defined herein as an angle of the sidewall 906 of each etched feature 908 relative to the axis 916, as well as a bottom 908A profile of the features 908 which may include a bottom width 910 discussed below and/or a flatness of the bottom 908A. While each of the top 912 and bottom 910 widths are shown in FIG. 9 as being substantially similar among and between the features 908 formed, in alternate embodiments, some of the features 908 of the plurality of features 908 is spaced at unequal distances. In an embodiment, a width 920 of a first target portion 902A is the same as a width 922 of a second target portion 902B formed in between the features 908 in the target layer 902. In another embodiment, the width 920 of a first target portion 902A is different from the width 922 of a second target portion 902B formed in between the features 908 in the target layer 902. In an embodiment, the plurality of etched features 908 discussed herein is a plurality of high AR holes, with aspect ratios of greater than 20:1. Thus, FIG. 9 illustrates a plurality of features 908 formed in a similar manner to those formed in FIGS. 3-6 as discussed in the method 200 above.

While the foregoing is directed to embodiments of the present disclosure, other and further embodiments of the disclosure may be devised without departing from the basic scope thereof, and the scope thereof is determined by the claims that follow.

What is claimed is:

1. A method for etching a substrate, comprising:
providing an ionizable gas mixture to a processing chamber of an etch reactor, wherein the ionizable gas mixture comprises C₃H₂F₄ and C₃F₆;
forming a plasma from the ionizable gas mixture, wherein forming the plasma comprises producing a plurality of ions from ionizable gas mixture; and
etching a stack, the stack including a plurality of alternating oxide and nitride layers formed on a substrate using the plurality of ions to form a plurality of features through the stack, wherein an aspect ratio of each feature of the plurality of features is from 20:1 to 100:1.

2. The method of claim 1, wherein etching the stack comprises etching the plurality of features to an average depth from about 4000 nm to about 8500 nm.

3. The method of claim 1, wherein etching the stack comprises etching the plurality of alternating oxide layers and nitride layers, wherein the oxide layers are etched at a first etch rate that is within 2% of a rate at which the nitride layers are etched.

4. The method of claim 1, further comprising etching the stack to form the plurality of features comprising an aspect ratio of 40:1 to 100:1.

5. The method of claim 1, further comprising providing a carrier gas to the processing chamber simultaneously with the ionizable gas mixture.

6. The method of claim 5, wherein a volume percentage ratio of the ionizable gas mixture to the carrier gas in the processing chamber is from 80:20 to 30:70.

7. The method of claim 1, wherein a volume percentage ratio of C₃F₆:C₃H₂F₄ in the ionizable gas mixture is from 10:90 to 70:30.

8. The method of claim 1, wherein a volume percentage ratio of C₃F₆:C₃H₂F₄ in the ionizable gas mixture is from 15:85 to 25:75.

9. The method of claim 1, further comprising maintaining, during the etching, an RF source power from 2500 W to 4500 W and an RF bias power from 10000 W to 20000 W.

10. The method of claim 1, prior to providing an ionizable gas mixture to a processing chamber, pre-heating the processing chamber to a temperature from about 0° C. to about 80° C. and a pressure from about 5 mT to about 50 mT.

11. A method of etching an oxide-nitride stack, comprising:
disposing, in a processing chamber, a gas mixture comprising: C₃H₂F₄, a companion gas, and O₂, wherein C₃H₂F₄ comprises a volume % of the gas mixture from 15 vol. % to 45 vol. %, the companion gas comprises a volume % of the gas mixture from 15 vol. % to 50 vol. %, and the O₂ comprises a volume % of the gas mixture from 10 vol. % to 40 vol. %;
subsequently, disposing a substrate in the processing chamber, wherein the substrate comprises a plurality of alternating oxide and nitride layers; and
etching, in response to exposure to the gas mixture, a plurality of features in the plurality of alternating oxide and nitride layers.

12. The method t of claim 11, wherein the companion gas comprises C₃F₆, C₄F₆, or C₄F₈.

13. A method comprising:
providing an ionizable gas mixture to a processing chamber of an etch reactor, a substrate being positioned in the processing chamber, wherein the ionizable gas mixture comprises C₃H₂F₄ and a companion gas;
forming a plasma from the ionizable gas mixture; and
etching, via the plasma, a stack comprising a plurality of alternating oxide and nitride layers to form a plurality of holes through the stack to selectively expose portions of the substrate.

14. The method of claim 13, further comprising maintaining, during etching, an RF source power from 2500 W to 4500 W, an RF bias power from 10000 W to 20000 W, and a frequency of 50 MHz-200 MHz during the etching.

15. The method of claim 13, further comprising etching the stack to form the plurality of holes such that each hole of the plurality of holes comprises an aspect ratio from 20:1 to 100:1.

16. The method of claim 13, wherein the method further comprises disposing O₂ in the processing chamber and wherein disposing the companion gas comprises disposing a gas according to a formula CₓF_{y}, wherein x is at least 1 and y is at least 1.

17. The method of claim 16, wherein a volume percentage ratio of the ionizable gas mixture:O₂ in the processing chamber is from 90:10 to 60:40.

18. The method of claim 13, wherein etching the stack comprises etching the plurality of alternating oxide layers and nitride layers, wherein the oxide layers are etched at a first etch rate that is within 2% of a rate at which the nitride layers are etched.

19. The method of claim 13, wherein a volume percentage ratio of the companion gas:C₃H₂F₄ in the ionizable gas mixture is from 10:90 to 40:60.

20. The method of claim 13, wherein the stack comprises a plurality of alternating oxide layers and nitride layers and wherein a ratio of an etch rate for the oxide layers to an etch rate of the nitride layers is about 1:1.
